(19) United States
(12) Patent Application Publication
(10) Pub. No.: US 2012/0319277 A1
(43) Pub. Date: Dec. 20, 2012

(54) THIN FILM TRANSISTOR PANEL AND MANUFACTURING METHOD THEREOF

(75) Inventors: Chiu-yi Chung, Shenzhen (CN); Cheng-ming He, Shenzhen (CN)

(73) Assignee: SHENZHEN CHINA STAR OPTOELECTRONICS TECHNOLOGY, CO., LTD., Shenzhen (CN)

(21) Appl. No.: 13/376,593

(22) PCT Filed: Aug. 11, 2011
(86) PCT No.: PCT/CN11/78312

§ 371 Date: Dec. 7, 2011

(30) Foreign Application Priority Data
Jun. 19, 2011 (CN) 201110164508.1

(51) Int. Cl. H01L 23/482; H01L 21/768

(52) U.S. Cl. 257/739; 438/665; 257/E23.012; 257/E21.575

(57) ABSTRACT

Disclosed is a thin film transistor panel, comprising a substrate, an insulation layer and transparent conducting material. The insulation layer comprises projections at the back side not facing the substrate. A space between two adjacent projections is 1 μm-10 μm; the transparent conducting material is formed on the top surface and the lateral surface of the projections of the insulation layer. Otherwise, the transparent conducting material is formed on the top surface and the plane surface around the bottom of the projections or formed on the top surface, the lateral surface and the plane surface around the bottom of the projections. The present invention also discloses a manufacturing method of the thin film transistor panel.

### BACKGROUND OF THE INVENTION

1. Field of the Invention

The present invention generally relates to a thin film transistor panel having a substrate, an insulation layer and transparent conducting material.

The present invention also relates to a manufacturing method of the thin film transistor panel, and more particularly to a thin film transistor panel having a substrate, an insulation layer and transparent conducting material and a manufacturing method thereof comprising steps of arranging the thin film transistor.

2. Description of Prior Art

In the thin film transistor panels in prior art, a gap exists between two adjacent strip shape transparent electrodes 4 as shown in FIG. 1. Because the electric field received by the liquid crystals in the area is insufficient and leads to low transmittance in these gap areas, the liquid crystals in the area are not tilted as shown in FIG. 2. As shown in FIG. 3, the effect of the liquid crystal display is restricted, a device with high resolution exposure function for manufacturing such thin film transistor panels is required and causes tremendous difficulty for the manufacturing processes.

Therefore, there is a need to provide a thin film transistor panel and manufacturing method thereof to solve the existing problems of prior art.

### SUMMARY OF THE INVENTION

An objective of the present invention is to provide a thin film transistor panel to solve the technical issues of the low transmittance and the restricted display effect due to the insufficient electric field received by the liquid crystals in the middle area of the thin film transistor panel.

For realizing the aforesaid objective, the present invention provides a thin film transistor panel comprising a substrate, an insulation layer and transparent conducting material. The insulation layer comprises projections at the back side opposite to the substrate, and a space between two adjacent projections is 1 μm-10 μm; The transparent conducting material is formed on the top surface and the lateral surface, on the top surface and the plane surface around the bottom or on the top surface, the lateral surface and the plane surface around the bottom of the projections of the insulation layer, and the insulation layer and the projections are formed by the same material and at the same layer; The transparent conducting material on the two adjacent projections are jointed as the transparent conducting material is formed on the top surface and the plane surface around the bottom, or on the top surface, the lateral surface and the plane surface around the bottom of the projections of the insulation layer; The transparent conducting material formed on the projections are strip shape or schistic shape; Heights of the projections are 10 nm-100 nm; Sectional shapes of the projections are regular or irregular.

In the thin film transistor panel of the present invention, a thickness difference of the two areas of the transparent conducting material is less than 10%.

In the thin film transistor panel of the present invention, the sectional shapes of the projections are selected from one of right trapezoid, isosceles trapezoid, rectangle, triangle, parallelogram and semi-circle.

Another objective of the present invention is to provide a thin film transistor panel to solve the technical issues of the low transmittance and the restricted display effect due to the insufficient electric field received by the liquid crystals in the middle area of the thin film transistor panel.

For realizing the aforesaid objective, the present invention provides a thin film transistor panel comprising a substrate, an insulation layer and transparent conducting material. The insulation layer comprises projections at the back side opposite to the substrate, and a space between two adjacent projections is 1 μm-10 μm; The transparent conducting material is formed on the top surface and the lateral surface, on the top surface and the plane surface around the bottom or on the top surface, the lateral surface and the plane surface around the bottom of the projections of the insulation layer, and the insulation layer and the projections are formed by the same material and at the same layer.

In the thin film transistor panel of the present invention, the transparent conducting material on the two adjacent projections are jointed as the transparent conducting material is formed on the top surface and the plane surface around the bottom, or on the top surface, the lateral surface and the plane surface around the bottom of the projections of the insulation layer.

In the thin film transistor panel of the present invention, the transparent conducting material formed on the projections is strip shape or schistic shape.

In the thin film transistor panel of the present invention, heights of the projections are 10 nm-100 nm.

In the thin film transistor panel of the present invention, sectional shapes of the projections are regular or irregular.

Another objective of the present invention is to provide a manufacturing method of a thin film transistor panel to solve the technical issues of the low transmittance and the restricted display effect due to the insufficient electric field received by the liquid crystals in the middle area of the thin film transistor panel.

For realizing the aforesaid objective, the present invention provides a manufacturing method of a thin film transistor panel comprising a substrate, an insulation layer and transparent conducting material, comprising a step of arranging thin film transistors, the method further comprises steps of: (A) forming the insulation layer on one side of the substrate opposite to a light source; (B) etching one side of the insulation layer opposite to the substrate to form projections, and a space between two adjacent projections is 1 μm-10 μm; (C) removing residue on the insulation layer generated in the etching step; (D) forming transparent conducting material on the etched side of the insulation layer.

In the manufacturing method of the thin film transistor panel of the present invention, the step (D) further comprises steps of: (d1) forming the transparent conducting material with a fixed thickness on the etched side of the insulation layer; or (d2) forming the transparent conducting material with a unfixed thickness on the etched side of the insulation layer, and a thickness of the transparent conducting material between the two adjacent projections is larger than a thickness of the transparent conducting material on the top surfaces of the projections; or (d3) forming the transparent conducting material with a unfixed thickness on the etched side of the insulation layer, and a thickness of the transparent conducting material between the two adjacent projections is smaller than a thickness of the transparent conducting material on the top surfaces of the projections.

In the manufacturing method of the thin film transistor panel of the present invention,

The manufacturing method of the thin film transistor panel of the present invention further comprises a step of: (d11) removing residue on the insulation layer after the step (d1).

In the manufacturing method of the thin film transistor panel of the present invention, the step (d2) further comprises steps of: (d21) etching the surface of the transparent conducting material between the two adjacent projections to regulate the thickness of the transparent conducting material; (d22) removing residue on the insulation layer after etching.

In the manufacturing method of the thin film transistor panel of the present invention, the step (d3) further comprises steps of: (d31) etching the surface of the transparent conducting material on the top surfaces of the projections to regulate the thickness of the transparent conducting material; (d32) removing residue on the insulation layer after etching.

Comparing with prior art, the present invention eliminates the blind area where the liquid crystals are not tilted between the two transparent electrodes and to uniform the transmittance and enhance the display effect.

For a better understanding of the aforementioned content of the present invention, preferable embodiments are illustrated in accordance with the attached figures for further explanation:

### BRIEF DESCRIPTION OF THE DRAWINGS

FIG. 1 shows a top view diagram of an area including a thin film transistor and a pixel of a thin film transistor panel according to prior art;

FIG. 2 shows a sectional diagram taken along line A-A′ of FIG. 1;

FIG. 3 shows a diagram of transmittance of the thin film transistor panel shown in FIG. 2;

FIG. 4 shows a top view diagram of a first preferable embodiment of a thin film transistor panel according to the present invention;

FIG. 5 shows a sectional diagram taken along line B-B′ of FIG. 4;

FIG. 6 shows a diagram of transmittance of the thin film transistor panel shown in FIG. 5;

FIG. 7 shows a diagram of a second preferable embodiment of a thin film transistor panel according to the present invention;

FIG. 8 shows a diagram of transmittance of the thin film transistor panel shown in FIG. 7;

FIG. 9 shows a top view diagram of a third preferable embodiment of a thin film transistor panel according to the present invention;

FIG. 10 shows a sectional diagram taken along line C-C′ of FIG. 9;

FIG. 11 shows a diagram of transmittance of the thin film transistor panel shown in FIG. 10;

FIG. 12 shows a diagram of a fourth preferable embodiment of a thin film transistor panel according to the present invention;

FIG. 13 shows a diagram of transmittance of the thin film transistor panel shown in FIG. 12;

FIG. 14 shows a diagram of a fifth preferable embodiment of a thin film transistor panel according to the present invention;

FIG. 15 shows a diagram of transmittance of the thin film transistor panel shown in FIG. 14;

FIG. 16 shows a flowchart of a preferable embodiment of a manufacturing method of the thin film transistor panel according to a preferable embodiment of the present invention.

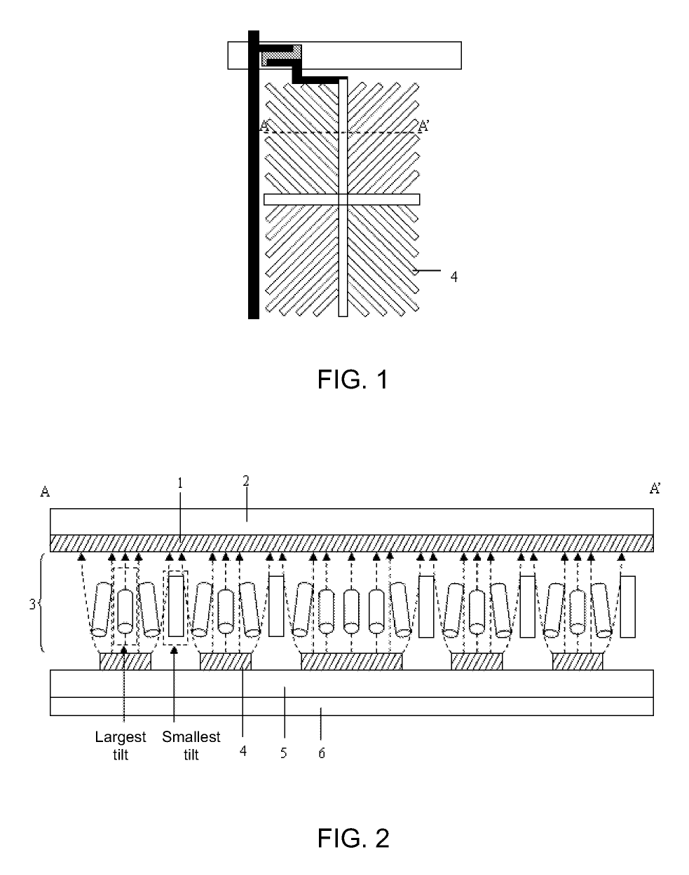

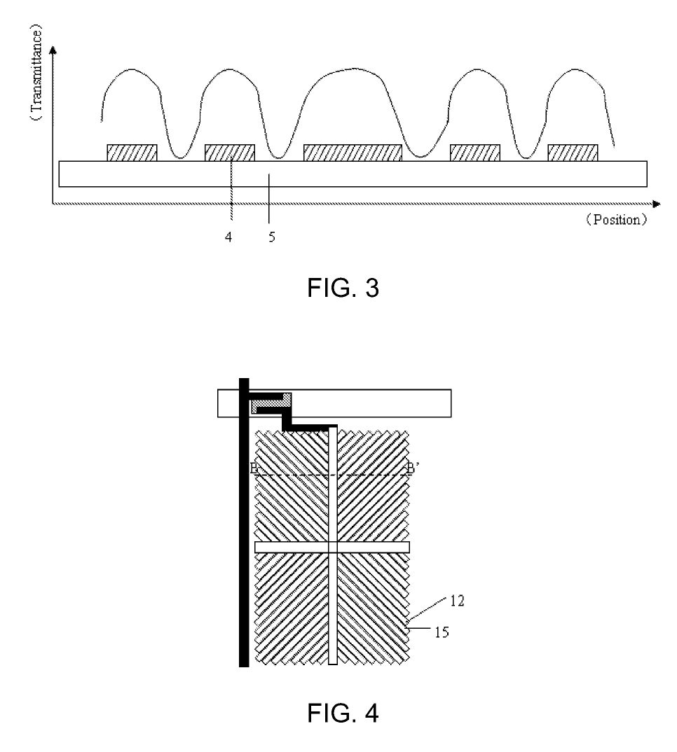

### DETAILED DESCRIPTION OF THE INVENTION

The following descriptions for the respective embodiments are specific embodiments capable of being implemented for illustrations of the present invention with referring to appended figures. For example, the terms of up, down, front, rear, left, right, interior, exterior, side, etcetera are merely directions of referring to appended figures. Therefore, the wordings of directions are employed for explaining and understanding the present invention but not limitations thereto.

In figures, the elements with similar structures are indicated by the same number.

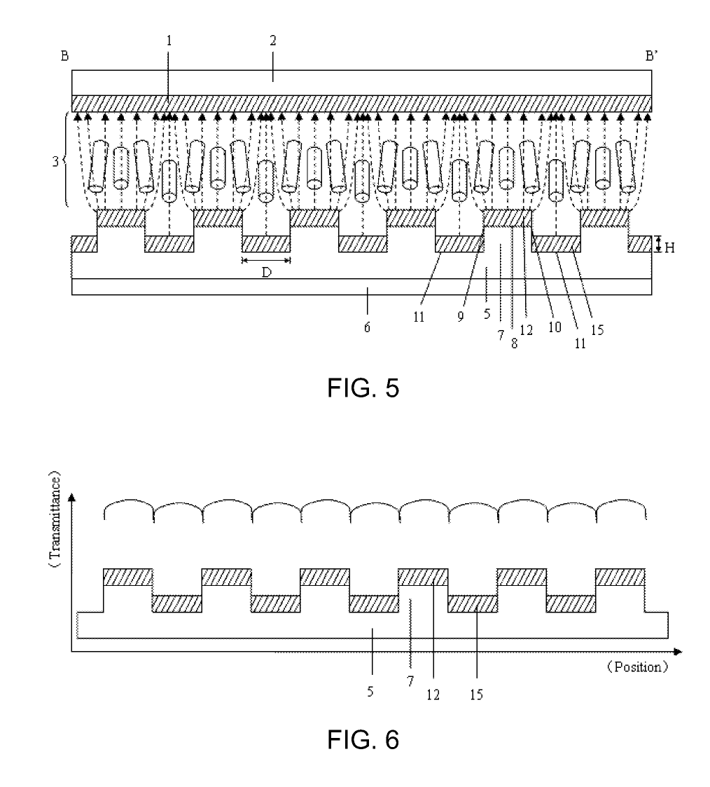

Please refer to FIG. 4 and FIG. 5. FIG. 4 shows a top view diagram of a first preferable embodiment of a thin film transistor panel according to the present invention. FIG. 5 shows a sectional diagram taken along line B-B′ of FIG. 4. The transparent conducting material (the first transparent conducting material 12 and the second transparent conducting material 15) is strip shape. The insulation layer 5 is positioned on the substrate 6. The insulation layer 5 comprises projections 7 at the back side opposite to the substrate 6. A projection 7 has a top surface 8, a first lateral surface 9 and a second lateral surface 10. In this embodiment, the sectional shape of the projection 7 is rectangle. The insulation layer 5 and the projection 7 formed by the same material and at the same layer. The first transparent conducting material 12 is formed on the top surface 8 of the projection 7. The second transparent conducting material 15 is formed on the plane surface 11 where the bottom of the projection 7 is positioned. The color filter 2 is positioned on the common electrode 1. The liquid crystal layer 3 is positioned between the common electrode 1 and the transparent conducting material (the first transparent conducting material 12 and the second transparent conducting material 15). In this embodiment, the second transparent conducting material 15 contacts the first lateral surface 9 of the projection 7 and the second lateral surface 10 of the adjacent projection 7. The thicknesses of the first transparent conducting material 12 and the second transparent conducting material 15 are fixed. Herein, the definition of the fixed thickness is that a thickness difference of any two areas selected from the first transparent conducting material 12 and the second transparent conducting material 15 is less than 10%. The height H of the projection 7 is specified in a range of 10 nm-100 nm. A space D between two adjacent projections is specified in a range of 1 μm-10 μm. In the present invention, Because the projections 7 are formed on the insulation layer 5 and the transparent conducting material is formed on the top surface 8 and the plane surface 11 around the bottom of the projection 7 (the first transparent conducting material 12 and the second transparent conducting material 15), the blind area where the liquid crystals are not tilted is eliminated and the transmittance is promoted. As shown in FIG. 6, the transmittance corresponding to the first transparent conducting material 12 and the transmittance corresponding to the second transparent conducting material 15 are pretty much the same. Meanwhile, a certain drop exists between the two transparent conducting materials in the vertical direction, i.e. the sources of the electric fields are in stagger arrangement to improve the effect of the electric field to the liquid crystals and to promote the transmittance.

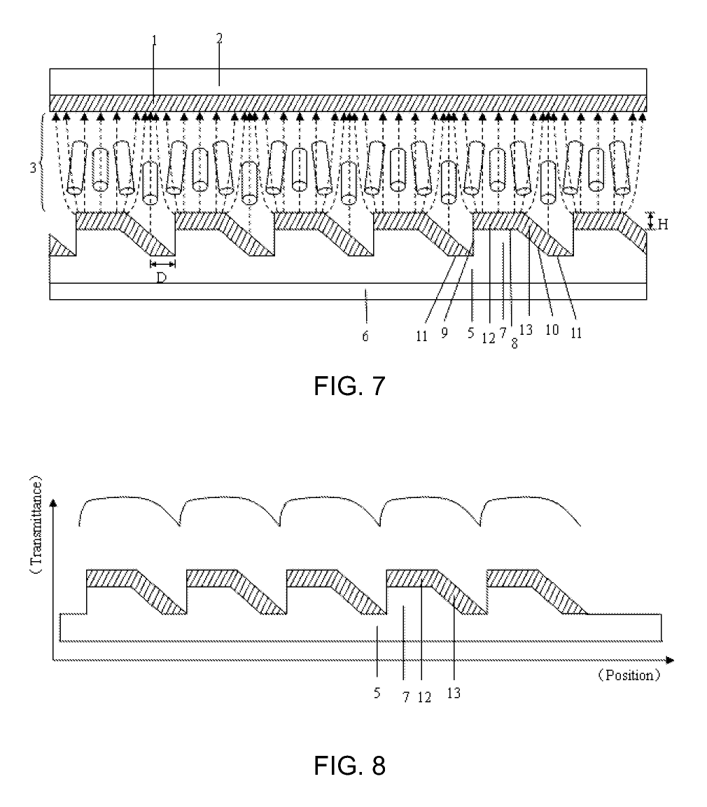

Please refer to FIG. 7, which shows a diagram of a second preferable embodiment of a thin film transistor panel according to the present invention. The transparent conducting material (the composition of the first transparent conducting material 12, the third transparent conducting material 13 and the second transparent conducting material 15) is strip shape. The top view diagram of this embodiment is similar to FIG. 4. The insulation layer 5 is positioned on the substrate 6. The insulation layer 5 comprises projections 7 at the back side opposite to the substrate 6. A projection 7 has a top surface 8, a first lateral surface 9 and a second lateral surface 10. The insulation layer 5 and the projection 7 formed by the same material and at the same layer. In this embodiment, the sectional shape of the projection 7 is right trapezoid. The first transparent conducting material 12 and the third transparent conducting material 13 are respectively formed on the top surface 8 and the second lateral surface 10 of the projection 7. The third transparent conducting material 13 extends to the plane surface 11 where the bottom of the projection 7 is positioned and connected with the second transparent conducting material 15. Preferably, the first transparent conducting material 12 is connected with the third transparent conducting material 13. The color filter 2 is positioned on the common electrode 1. The liquid crystal layer 3 is positioned between the common electrode 1 and the transparent conducting material (the composition of the first transparent conducting material 12, the third transparent conducting material 13 and the second transparent conducting material 15). The thicknesses of the first transparent conducting material 12 and the third transparent conducting material 13 are fixed. Herein, the definition of the fixed thickness is that a thickness difference of any two areas selected from the first transparent conducting material 12, the third transparent conducting material 13 and the second transparent conducting material 15 is less than 10%. The height H of the projection 7 is specified in a range of 10 nm-100 nm. A space D between two adjacent projections is specified in a range of 1 μm-10 μm. As shown in FIG. 8, the transmittance corresponding to the third transparent conducting material 13 and the transmittance corresponding to the first transparent conducting material 12 are pretty much the same, i.e. the blind area where the liquid crystals are not tilted between the two adjacent transparent conducting materials is eliminated.

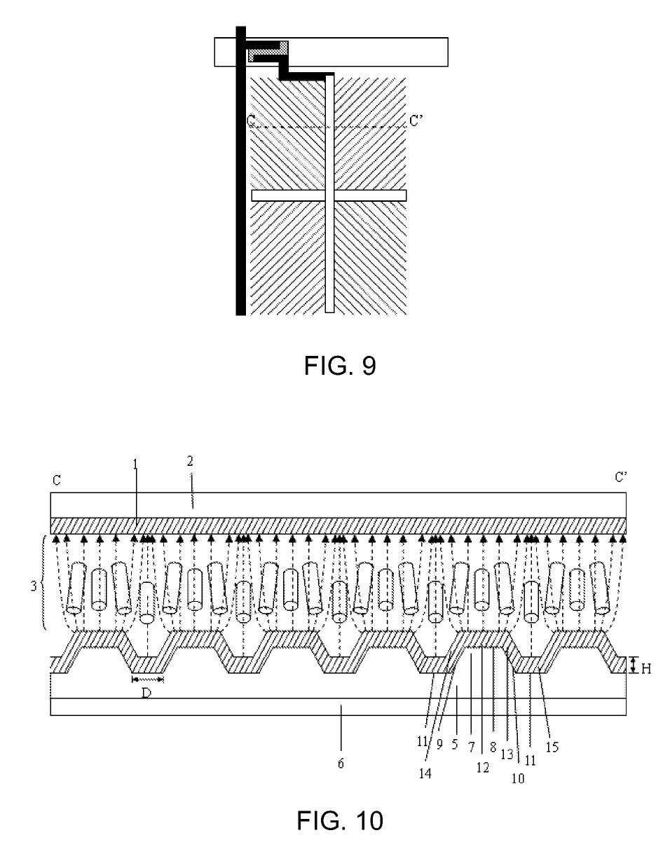

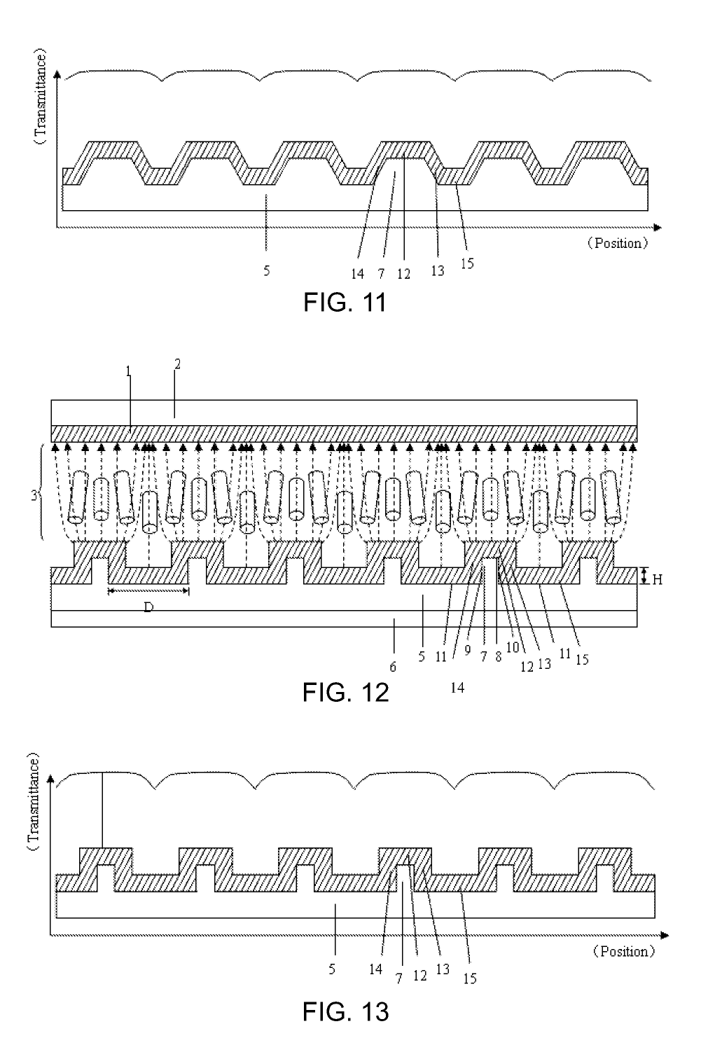

Please refer to FIG. 9 and FIG. 10. FIG. 9 shows a top view diagram of a third preferable embodiment of a thin film transistor panel according to the present invention. FIG. 10 shows a sectional diagram taken along line C-C′ of FIG. 9. The transparent conducting material (the composition of the first transparent conducting material 12, the second transparent conducting material 15, the third transparent conducting material 13 and the fourth transparent conducting material 14) is schistic shape. The insulation layer 5 is positioned on the substrate 6. The insulation layer 5 comprises projections 7 at the back side opposite to the substrate 6. A projection 7 has a top surface 8, a first lateral surface 9 and a second lateral surface 10. The sectional shape of the projection 7 is isosceles trapezoid. The insulation layer 5 and the projection 7 formed by the same material and at the same layer. The first transparent conducting material 12 is formed on the top surface 8. The third transparent conducting material 13 and the fourth transparent conducting material 14 are respectively formed on the first lateral surface 9 and the second lateral surface 10. The second transparent conducting material 15 is formed on the plane surface 11 around the bottom of the projection 7. The color filter 2 is positioned on the common electrode 1. The liquid crystal layer 3 is positioned between the common electrode 1 and the transparent conducting material (the composition of the first transparent conducting material 12, the second transparent conducting material 15, the third transparent conducting material 13 and the fourth transparent conducting material 14). The thicknesses of the first transparent conducting material 12, the second transparent conducting material 15, the third transparent conducting material 13 and the fourth transparent conducting material 14 are fixed. Herein, the definition of the fixed thickness is that a thickness difference of any two areas selected from the first transparent conducting material 12, the second transparent conducting material 15, the third transparent conducting material 13 and the fourth transparent conducting material 14 is less than 10%. The height H of the projection 7 is specified in a range of 10 nm-100 nm. A space D between two adjacent projections is specified in a range of 1 μm-10 μm. Please refer to FIG. 11, the transmittance curve is almost flat and therefore the trough of the transmittance curve appeared in prior art is eliminated and the display effect is promoted.

Please refer to FIG. 12, which shows a diagram of a fourth preferable embodiment of a thin film transistor panel according to the present invention. The transparent conducting material (the composition of the first transparent conducting material 12, the second transparent conducting material 15, the third transparent conducting material 13 and the fourth transparent conducting material 14) is schistic shape. The top view diagram of this embodiment is similar to FIG. 9. The insulation layer 5 is positioned on the substrate 6. The insulation layer 5 comprises projections 7 at the back side opposite to the substrate 6. A projection 7 has a top surface 8, a first lateral surface 9 and a second lateral surface 10. The sectional shape of the projection 7 is rectangle. The insulation layer 5 and the projection 7 formed by the same material and at the same layer. The first transparent conducting material 12 is formed on the top surface 8. The third transparent conducting material 13 and the fourth transparent conducting material 14 are respectively formed on the first lateral surface 9 and the second lateral surface 10. The second transparent conducting material 15 is formed on the plane surface 11 around the bottom of the projection 7. The transparent conducting materials on the two adjacent projections 7 are connected. The color filter 2 is positioned on the common electrode 1. The liquid crystal layer 3 is positioned between the common electrode 1 and the transparent conducting material (the composition of the first transparent conducting material 12, the second transparent conducting material 15, the third transparent conducting material 13 and the fourth transparent conducting material 14). The thicknesses of the first transparent conducting material 12, the second transparent conducting material 15, the third transparent conducting material 13 and the fourth transparent conducting material 14 are fixed. Herein, the definition of the fixed thickness is that a thickness difference of any two areas selected from the first transparent conducting material 12, the second transparent conducting material 15, the third transparent conducting material 13 and the fourth transparent conducting material 14 is less than 10%. The height H of the projection 7 is specified in a range of 10 nm-100 nm. A space D between two adjacent projections is specified in a range of 1 μm-10 μm. As shown in FIG. 13, the transmittance curve is almost flat and therefore the trough of the transmittance curve appeared in prior art is eliminated and the display effect is promoted.

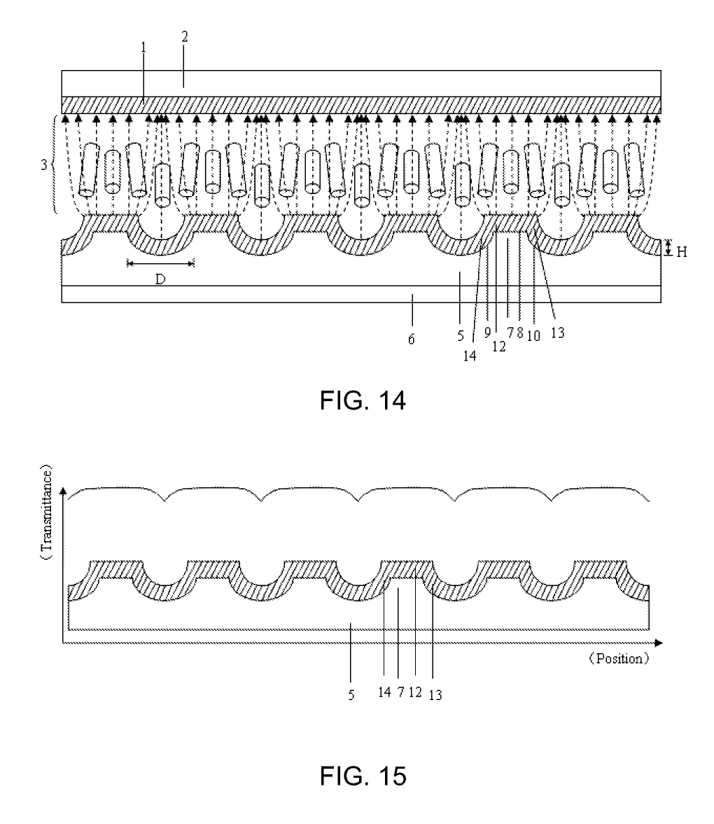

Please refer to FIG. 14, which shows a diagram of a fifth preferable embodiment of a thin film transistor panel according to the present invention. The transparent conducting material (the composition of the first transparent conducting material 12, the third transparent conducting material 13 and the fourth transparent conducting material 14) is schistic shape. The top view diagram of this embodiment is similar to FIG. 9. The insulation layer 5 is positioned on the substrate 6. The insulation layer 5 comprises projections 7 at the back side opposite to the substrate 6. A projection 7 has a top surface 8, a first lateral surface 9 and a second lateral surface 10. The shapes of the projections 7 are irregular. The first lateral surface 9 and the second lateral surface 10 of the projection 7 are both curved surfaces. Both the first lateral surface 9 and the second lateral surface 10 are a quarter of a circle arc surface. The insulation layer 5 and the projection 7 formed by the same material and at the same layer. The first transparent conducting material 12 is formed on the top surface 8. The third transparent conducting material 13 and the fourth transparent conducting material 14 are respectively formed on the first lateral surface 9 and the second lateral surface 10. The transparent conducting materials on the opposite lateral surfaces of the two adjacent projections 7 are connected. The color filter 2 is positioned on the common electrode 1. The liquid crystal layer 3 is positioned between the common electrode 1 and the transparent conducting material (the composition of the first transparent conducting material 12, the third transparent conducting material 13 and the fourth transparent conducting material 14). The thicknesses of the first transparent conducting material 12, the third transparent conducting material 13 and the fourth transparent conducting material 14 are fixed. Herein, the definition of the fixed thickness is that a thickness difference of any two areas selected from the first transparent conducting material 12, the third transparent conducting material 13 and the fourth transparent conducting material 14 is less than 10%. The height H of the projection 7 is specified in a range of 10 nm-100 nm. A space D between two adjacent projections is specified in a range of 1 μm-10 μm. As shown in FIG. 15, the transmittance curve is almost flat and therefore the trough of the transmittance curve appeared in prior art is eliminated and the display effect is promoted.

In the thin film transistor panel according to the present invention, the sectional shape of the projection 7 also can be triangle, parallelogram, semi-circle and other regular shape. Alternatively, the sectional shape of the projection 7 can be irregular shape.

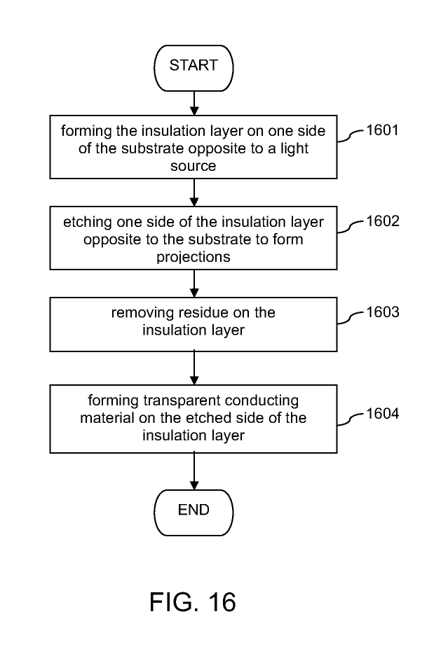

Please refer to FIG. 16, which shows a flowchart of a preferable embodiment of a manufacturing method of the thin film transistor panel according to a preferable embodiment of the present invention. In step 1601, forming the insulation layer on one side of the substrate opposite to a light source; In step 1602, etching one side of the insulation layer opposite to the substrate to form projections, and a space between two adjacent projections is 1 μm-10 μm; In step 1603, removing residue on the insulation layer generated in the etching step; In step 1604, forming transparent conducting material on the etched side of the insulation layer. Specifically, magnetron sputtering o deposition can be employed to form the transparent conducting material with a fixed thickness on the etched side of the insulation layer. The fixed thickness herein is that a thickness difference of two areas of the transparent conducting material is less than 10%; besides, the transparent conducting material with a unfixed thickness can be formed on the etched side of the insulation layer by deposition. Herein the unfixed thickness is that the thickness difference of the transparent conducting material between the two adjacent projections (including the first lateral surface 9, the second lateral surface 10 and the plane surface 11 where the bottom of the projection 7 is positioned) and the transparent conducting material on the top surface 8 is larger than 10%. Specifically, if the former is larger than the latter, the surface of the transparent conducting material between the two adjacent projections is etched to regulate the thickness of the transparent conducting material. Herein, the thickness consistency is that a thickness difference of two areas of the transparent conducting material is less than 10%. After the etching, the residue on the insulation layer is removed. If the former is less than the latter, the surface of the transparent conducting material on the top surfaces of the projections is etched to regulate the thickness of the transparent conducting material. Herein, the thickness consistency is that a thickness difference of two areas of the transparent conducting material is less than 10%. After the etching, the residue on the insulation layer is removed.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A thin film transistor panel comprising a substrate, an insulation layer and transparent conducting material, characterized in that:
the insulation layer comprises projections at the back side opposite to the substrate, and a space between two adjacent projections is 1 μm-10 μm;
the transparent conducting material is formed on the top surface and the lateral surface, on the top surface and the plane surface around the bottom or on the top surface, the lateral surface and the plane surface around the bottom of the projections of the insulation layer, and the insulation layer and the projections are formed by the same material and at the same layer;
the transparent conducting material on the two adjacent projections are jointed as the transparent conducting material is formed on the top surface and the plane surface around the bottom, or on the top surface, the lateral surface and the plane surface around the bottom of the projections of the insulation layer;
the transparent conducting material formed on the projections are strip shape or schistic shape;
heights of the projections are 10 nm-100 nm;
sectional shapes of the projections are regular or irregular.

2. The thin film transistor panel according to claim 1, characterized in that a thickness difference of two areas of the transparent conducting material is less than 10%.

3. The thin film transistor panel according to claim 1, characterized in that the sectional shapes of the projections are selected from one of right trapezoid, isosceles trapezoid, rectangle, triangle, parallelogram and semi-circle.

4. A thin film transistor panel, comprising a substrate, an insulation layer and transparent conducting material, characterized in that:
the insulation layer comprises projections at the back side opposite to the substrate, and a space between two adjacent projections is 1 μm-10 μm;
the transparent conducting material is formed on the top surface and the lateral surface, on the top surface and the plane surface around the bottom or on the top surface, the lateral surface and the plane surface around the bottom of the projections of the insulation layer, and the insulation layer and the projections are formed by the same material and at the same layer.

5. The thin film transistor panel of claim 4, characterized in that the transparent conducting material on the two adjacent projections are jointed as the transparent conducting material is formed on the top surface and the plane surface around the bottom, or on the top surface, the lateral surface and the plane surface around the bottom of the projections of the insulation layer.

6. The thin film transistor panel according to claim 4, characterized in that the transparent conducting material formed on the projections are strip shape or schistic shape.

7. The thin film transistor panel according to claim 4, characterized in that heights of the projections are 10 nm-100 nm.

8. The thin film transistor panel according to claim 4, characterized in that sectional shapes of the projections are regular or irregular.

9. A manufacturing method of a thin film transistor panel comprising a substrate, an insulation layer and transparent conducting material, comprising a step of arranging thin film transistors characterized in that the method further comprises steps of:
(A) forming the insulation layer on one side of the substrate opposite to a light source;
(B) etching one side of the insulation layer opposite to the substrate to form projections, and a space between two adjacent projections is 1 μm-10 μm;
(C) removing residue on the insulation layer generated in the etching step;
(D) forming transparent conducting material on the etched side of the insulation layer.

10. The manufacturing method of the thin film transistor panel according to claim 9, characterized in that the step (D) further comprises steps of:
(d1) forming the transparent conducting material with a fixed thickness on the etched side of the insulation layer; or
(d2) forming the transparent conducting material with a unfixed thickness on the etched side of the insulation layer, and a thickness of the transparent conducting material between the two adjacent projections is larger than a thickness of the transparent conducting material on the top surfaces of the projections; or
(d3) forming the transparent conducting material with a unfixed thickness on the etched side of the insulation layer, and a thickness of the transparent conducting material between the two adjacent projections is smaller than a thickness of the transparent conducting material on the top surfaces of the projections.

11. The manufacturing method of the thin film transistor panel according to claim 10, characterized in further comprising a step of:
(d11) removing residue on the insulation layer after the step (d1).

12. The manufacturing method of the thin film transistor panel according to claim 10, characterized in that the step (d2) further comprises steps of:
(d21) etching the surface of the transparent conducting material between the two adjacent projections to regulate the thickness of the transparent conducting material;
(d22) removing residue on the insulation layer after etching.

13. The manufacturing method of the thin film transistor panel according to claim 10, characterized in that the step (d3) further comprises steps of:
(d31) etching the surface of the transparent conducting material on the top surfaces of the projections to regulate the thickness of the transparent conducting material;
(d32) removing residue on the insulation layer after etching.
